(19) United States
(12) Patent Application Publication
(10) Pub. No.: US 2022/0338344 A1
(43) Pub. Date: Oct. 20, 2022

(54) PHASE HETEROGENEOUS INTERCONNECTS FOR CROSSTALK REDUCTION

(71) Applicant: Intel Corporation, Santa Clara, CA (US)

(72) Inventors: Zhen Zhou, Chandler, AZ (US); Gordon Melz, Beaverton, OR (US); Daqiao Du, Lake Oswego, OR (US); Ismael Franco, Milwaukie, OR (US); Jason Mix, Portland, OR (US)

(73) Assignee: Intel Corporation, Santa Clara, CA (US)

(21) Appl. No.: 17/855,680

(22) Filed: Jun. 30, 2022

(51) Int. Cl. H05K 1/02; H05K 1/11

(52) U.S. Cl. CPC H05K 1/0228; H05K 1/0298; H05K 1/115; H05K 2201/09545

(57) ABSTRACT

Methods and apparatus relating to phase heterogeneous interconnects for crosstalk reduction are described. In one embodiment, an interconnect includes a plurality of links. A first set of links from the plurality of links communicates signals and a second set of links from the plurality of links provides a return path. The interconnect also includes one or more links from the first set of links that include one or more structures with a larger diameter than a minimum diameter of the one or more links. The larger diameter modifies an inductance or capacitance of the one or more links to provide a heterogenous phase delay amongst the plurality of links. Other embodiments are also claimed and disclosed.

### FIELD

The present disclosure generally relates to the field of electronics. More particularly, an embodiment relates to phase heterogeneous interconnects for crosstalk reduction.

### BACKGROUND

Interconnects used in many socket designs can introduce an appreciable amount of crosstalk, particularly when the interconnects are relatively long with a small separation between adjacent links in the interconnect. The crosstalk, in turn, may cause signal propagation delays, signal loss, and/or errors.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 illustrates various views of interconnect improvements that may be used in one or more embodiments.

FIG. 1-1 illustrates sample shape for one or more inductive features, according to an embodiment.

FIG. 2 illustrates a perspective view of contrasting examples using a multi-layer Printed Circuit Board (PCB), according to an embodiment.

FIG. 3 illustrates a sample routing configuration with serpentine lines to match delays.

FIG. 4 illustrates a phase delay capable via, according to an embodiment.

FIG. 5 illustrates a block diagram of an embodiment of a computing system, which may be utilized in various embodiments discussed herein.

FIG. 6 illustrates a block diagram of an embodiment of a computing system, which may be utilized in various embodiments discussed herein.

FIG. 7 illustrates various components of a processer in accordance with some embodiments.

### DETAILED DESCRIPTION

In the following description, numerous specific details are set forth in order to provide a thorough understanding of various embodiments. However, various embodiments may be practiced without the specific details. In other instances, well-known methods, procedures, components, and circuits have not been described in detail so as not to obscure the particular embodiments. Further, various aspects of embodiments may be performed using various means, such as integrated semiconductor circuits (“hardware”), computer-readable instructions organized into one or more programs (“software”), or some combination of hardware and software. For the purposes of this disclosure reference to “logic” shall mean either hardware (such as logic circuitry or more generally circuitry or circuit), software, firmware, or some combination thereof.

As mentioned above, some current interconnect designs suffer from an appreciable amount of crosstalk which may, in turn, cause signal propagation delays, signal loss, and/or errors. To this end, some embodiments relate to phase heterogeneous interconnects for crosstalk reduction. In one embodiment, a phase diversified interconnect design is introduced to mitigate the overall crosstalk impacts imposed on a victim link from its adjacent aggressor(s) link(s), while maintaining the interconnect height/length and relatively small separations between the adjacent interconnect links. As discussed herein, an interconnect “link” generally refers to a signal path from an originator (such as a transmitter) to a destination (such as a receiver). Further, the terms interconnect link, link, an interconnect transmission line, a wire, or a pin from a plurality of links that may be interchangeable. In at least one embodiment, the interconnects discussed herein may utilize a differential signal pair which utilizes two wires to form a differential signal path.

In an embodiment, heterogeneous interconnects with diverse phase velocities are used to mitigate the overall crosstalk imposed upon a victim link from different adjacent aggressor link(s). The diverse phase velocities may be provided by adding capacitive diaphragms, e.g., to alter the phase velocities of each individual interconnect link. Such embodiments are envisioned to: (a) provide a higher data rate while the package density and the platform form factor remain unchanged; (b) maintain the mechanical stability of the interconnect; and/or (c) provide compatibility with at least some current Printed Circuit Board (PCB) and test socket pin fabrication technologies. Hence, there is little or no addition cost associated with implementation of one or more embodiments.

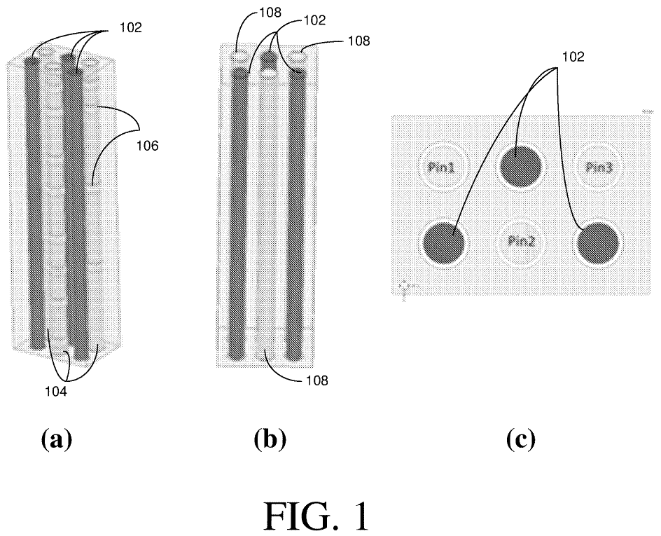

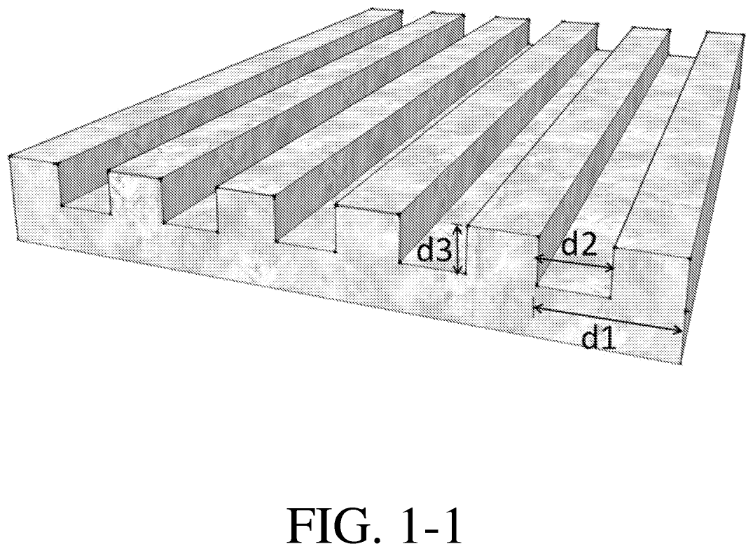

FIG. 1 illustrates various views of interconnect improvements that may be used in one or more embodiments. More particularly, FIG. 1(a) illustrates a perspective view of a phase heterogeneous interconnect in accordance with an embodiment. FIG. 1(b) illustrates a perspective view of a conventional homogeneous interconnect. FIG. 1(c) illustrates top view of a pin map of the interconnect shown in FIGS. 1(a) and 1(b). While some embodiments illustrate a vertical interconnect, embodiments are not limited to this and an interconnect may have other orientations such as planar.

As shown in FIG. 1(a), the interconnect is heterogenous, e.g., where some of the interconnect links have a uniform shape along the vertical direction (102), while other interconnect links (104) have circular diaphragms or other structures/features (106) at different locations along the vertical direction. While some embodiments, show the feature(s) 106 to have a circular shape, embodiments are not limited to circular shapes and other shapes may be used for these structures. For example, the feature(s) 106 may have a circular shape, a square shape, a rectangular shape, a sawtooth shape, or combinations thereof. Also, in at least one embodiment, a non-spring-loaded stamp pin may have a rectangular or other shape in their cross section. Additionally, while some embodiments utilize a capacitive addition as the feature(s) 106, embodiments are not limited to capacitive features and one or more inductive additions (such as corrugated shapes, e.g., fan blade(s), etc.) may be utilized (alone or in addition to the capacitive addition(s)) as the feature(s) 106.

FIG. 1-1 illustrates sample shape for one or more inductive features, according to an embodiment. As shown, the inductive addition may take a shape such as a corrugated surface along the vertical interconnect height. Labels d1-d3 are provided to indicate that the various illustrated dimensions may be configurable and may or may not be the same. Besides this shape, other shapes may be used (e.g., for features 106) such as a spiral shape along the vertical interconnect (alone or in combination with the corrugated shape). For the planar interconnects, other choices may be used for the feature shapes. Such embodiments are envisioned to provide an additional current path length to increase the inductance of the interconnects and change the phase velocity in that way.

Referring to FIG. 1(b), the interconnect links are uniform along the vertical direction and the structures 106 are absent. FIG. 1(c) illustrates the relative distribution of the interconnect links/pins from for the interconnects of FIGS. 1(a) and 1(b). Pins 1-3 are signal pins (corresponding to the links 104 of FIG. 1(a) and links 108 of FIG. 1(b)) and the remaining pins (102) are ground pins.

In an embodiment, the circular diaphragms or other structures 106 provide a capacitively loaded transmission line. For a homogenous transmission line, the phase velocity is given by:

Vₚ=\sqrt{LC}=\sqrt{μᵣμ₀εᵣε₀} (1)

where εᵣ is the dielectric permittivity and μᵣ is the magnetic permeability of the medium surrounding the transmission line. The phase velocity cannot be decreased by increasing the shunt capacity C per unit length because any change in the line configuration to increase C automatically decreases the series inductance L per unit length, since:

LC=μ₀ε (2)

However, by removing the restriction that the transmission line should by physically smooth, an effective increase in the shunt capacitance per unit length can be achieved without a corresponding decrease in the series inductance L. That is, lumped shunt capacitance may be added at periodic intervals without affecting the value of L. If the spacing between the added lumped capacitors is small compared to the wavelength, it may be anticipated that the transmission line will appear to be electrically smooth, with a phase velocity by adding an additional:

$${V}_{p} = \sqrt{L ( C + \frac{{C}_{0}}{d} )} \qquad ( 3 )$$

where C₀/d is the amount of lumped capacitance added per unit length (where a capacitor Co added at intervals d).

By introducing different C₀/d values, the phase velocity of a transmission line can be altered. To maintain the impedance of the transmission line with no change, L can be adjusted accordingly. Besides the periodical loading of the transmission line capacitively, non-periodically loading of the transmission line provides much more flexibility to truly diversify the phase of which a transmission provides, and hence enables phase heterogeneous interconnects for crosstalk cancelation.

Accordingly, some embodiments provided one or more of the following: (a) phase velocity heterogeneous spring-loaded pins for a high-volume testing socket; (b) phase heterogeneous vias in a PCB; and/or (c) phase heterogeneous routing for a package PCB. As discussed herein, a “via” generally refers to a plated through-hole via or partial through-hole via (sometimes referred to as a blind or buried via) which may be utilized to communicate a signal between one or more layers of a PCB and/or between surface pads and one or more layers of the PCB. The (e.g., metal including copper, nickel, aluminum, etc.) plating of a via allows for the via to become electrically conductive. The PCBs discussed herein may mechanically couple the plurality of links. Further, a PCB may be surface finished with Hot Air Solder Leveling (HASL) finish, lead free HASL finish, or Electroless Nickel Immersion Gold (ENIG) finish.

### Phase Velocity Heterogeneous Spring-Loaded Pins for a High-Volume Testing Socket

Referring to FIG. 1, a phase velocity heterogeneous pin design is presented in FIG. 1(a) pictorially. As a comparison, the phase velocity homogeneous pin design is shown in FIG. 1(b). Contrary to the phase velocity homogeneous pin design in which each of the pins is the same along its height, the phase heterogeneous pin design utilizes pins with diverse phase velocities. The alteration of the phase velocity for each signal pin is accomplished by adding circular diaphragms or other structures 106 along the pin either periodically or non-periodically. By varying the period of the circular diaphragms or structures and/or the location of them, the phase velocity of the signal propagating through each signal pin can be changed.

Moreover, the diameter of the pin structure and outer diameter of the circular diaphragms/features and/or thickness may be used to tune the inductance of that pin. For the tuning to take effect and show phase angle distribution, the structural diameters of the circular diaphragms/features are between approximately 20% and 30% more than the pin structure diameter in an embodiment. If the pin diameter is more than approximately 30% less the circular diaphragm diameter, then the pin inductance would not be enough to make a phase change. Thickness if the circular diaphragms is important along with the placement of these features along a signal pin to change the phase angle and interaction of adjacent pins. Pins adjacent to each other with different thickness in circular diaphragms show phase angle difference.

Further, both designs (FIGS. 1(a) and 1(b)) are envisioned to have the same pitch, same height, and same signal to ground ratio. Since the pitches for those two designs are identical, their near end crosstalk (NEXT) values are identical. However, the two aggressors in the heterogeneous pin design of FIG. 1(a) induce different far end crosstalk (FEXT) values in both magnitudes and phases while the two aggressors in the homogeneous pin design of FIG. 1(b) impose identical FEXT values. Additionally, the heterogeneous pin design of FIG. 1(a) is envisioned to improve the signal-noise ratios over the homogeneous pin design of FIG. 1(b). Moreover, to obtain the desired information at the receiver end, the signal strength may be boosted and/or the noise level (e.g., with FEXT and NEXT as part of noise) may need to be reduced in some embodiments. In one example, the signal strength is fixed and the noise level is reduced. At least one embodiment provides an improved signal to noise ratio (S/N) for heterogeneous pins.

### Phase Heterogeneous Vias in a PCB

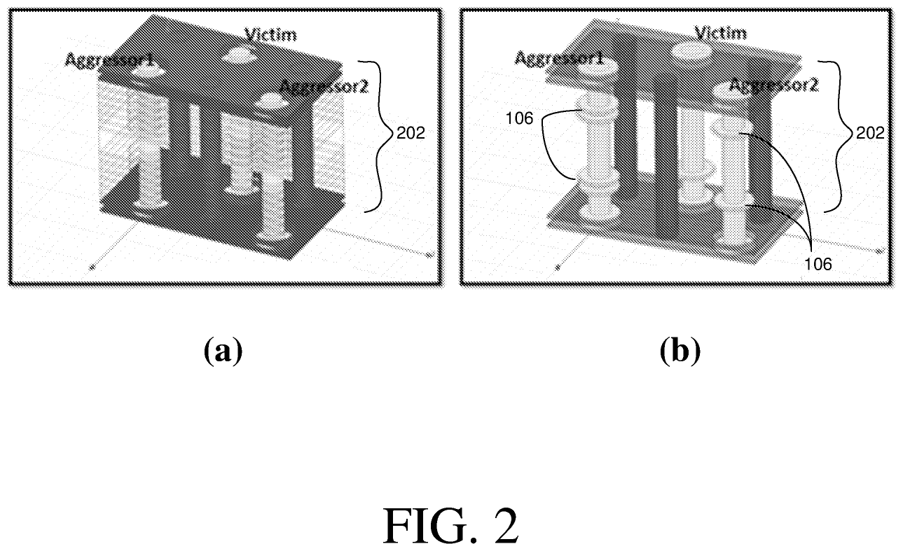

Since much of the crosstalk that exists in a channel generally occur at the PCB layer transitions, one or more embodiments can also be applied as phase heterogeneous vias in PCB. As discussed herein, a “channel” generally refers to an electrical channel that includes an entire path from silicon driver circuit (TX) through its substrate package and/or solder joint, and then to main board traces and vias, finally reaching the solder joint, substrate package and silicon receiver circuit (RX). Also, as discussed herein, a “pad stack” refers to all features associated with a conductive circular disk surrounding a hole in a PCB including, for example, Plated Through-Hole (PTH) vias might have pads extending out at each PCB layer. These extended pads can be left used as-is, omitted, or enlarged to modify the via parasitic properties and change the phase of the signal as it propagates through. FIG. 2 illustrates a perspective view of contrasting examples using a 14-layer PCB, according to an embodiment. The PCB 202 may be 1.56 millimeters (mm) thick, with vias at 0.65 mm pitch. Signal vias are marked with “victim” and aggressor” labels. The remaining pins indicate return paths (e.g., ground). In this example, the outer two vias are considered “Aggressors” with some of their energy coupling onto the third “Victim” via.

Moreover, FIG. 2(a) shows a uniform pad stack via and FIG. 2(b) shows a phase heterogeneous vias. By adjusting the via pad stack the phase from the aggressing vias can be shifted. Using vias with uniform pad stacks and with similar PTH ground patterns means that the phase velocity of the signals will be the same in all cases. This means the coupling from Aggressor1 and Aggressor2 will be in phase as it couples onto the Victim via. By adjusting the via pad stack, the phase can be adjusted for each case. Doing so will result in having each aggressing via at a different phase.

One or more embodiments vary the pad stack details of a via in a multi-layer PCB to tune/modify the self-capacitance of the via. As discussed herein, “self-capacitance” of a via generally refers to the electrical charge to which the via can be charged. For example, if a via pad/structure 106 is included in every layer, the self-capacitance will be at its maximum value. This capacitance will decrease the signal velocity factor of the signal as it propagates through the vertical transition, resembling a longer electrical length as compared to a via with only the top and bottom pads present, for example. In an embodiment, the number of via pads/structures 106 may be varied to modify the resulting signal velocity factor, e.g., between a slow, medium, fast, etc. propagation. As discussed herein, a “signal velocity” generally refers to the speed at which a wave carries information and the term “propagation” refers to the time period it takes a wave to carry the information from one end (TX) to another end (RX).

In one embodiment, a set of via pad stack symbols for a given stack-up can be set as “slow_via,” “med_via,” “fast_via,” etc. A Computer Aided Design (CAD) engineer would simply need to alternate between these symbols as (e.g., High Speed Input/Output (HSIO)) signals are routed. Alternatively, a script could be written to automatically alternate between these symbols for a given set of traces (e.g., memory Data Quality (DQ) bits, Universal Serial Bus (USB) differential pairs, Peripheral Component Interconnect express (PCIe) differential pairs, Transmission Control Protocol (TCP) differential pairs, etc.). Further, in at least one embodiment, the phase tuning approach is considered to be dependent primarily on the via parasitics (e.g., introduced via pads/structures 106) and any effects from the other stack-up details are envisioned to be secondary.

### Phase Heterogeneous Routings for Silicon Package to Package or to the Connector on PCB Board

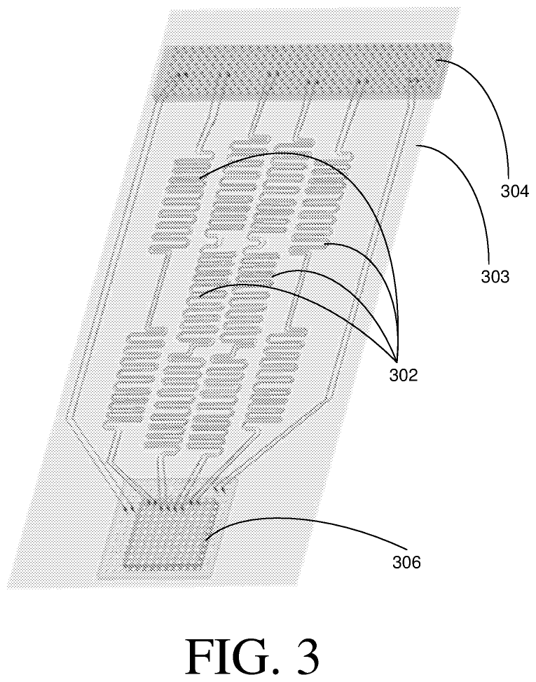

FIG. 3 illustrates a sample routing configuration with serpentine lines to match delays. As shown in FIG. 3, a routing method to compensate the phase difference may employ the serpentine lines 302 in fan-out routing cases on a PCB 303. This method has some disadvantages such as: (1) it requires more real estate and forces a connector 304 and Integrated Circuit (IC) chip(s) 306 further apart; (2) it fails to guarantee the phase match since it ignores vertical transition delay variations; (3) the serpentine line 302 impedance is hard to under control tightly due to self-capacitance effects; and/or (4) it introduces more crosstalk if it is not done properly.

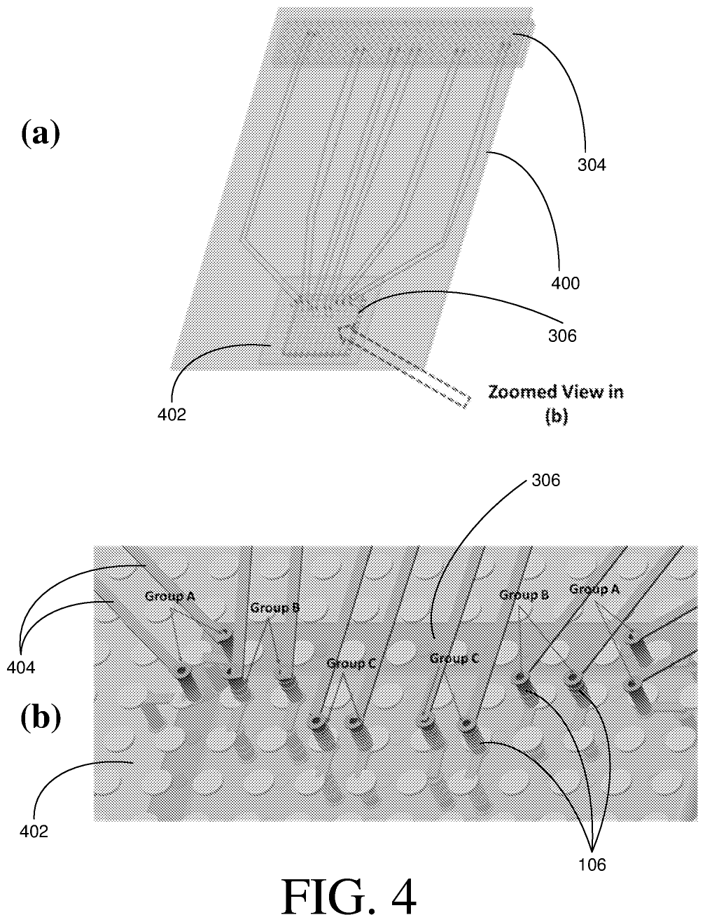

FIG. 4 illustrates a phase delay capable via, according to an embodiment. FIG. 4(a) illustrates an overall view of a PCB 400 and FIG. 4(b) illustrates a zoomed/exploded view of the phase delay capable vias.

As revealed in the zoomed view of the phase delay capable vias shown in FIG. 4(b), the delay of each line may be controlled by the via pad stack (e.g., the number of pads 106 and/or pad diameters) included in the connection of the IC chip 306 to the package 402 through the vias shown in FIG. 4(b). More pads generally mean a longer delay (“slow via”). For instance, the outmost traces 404 may connect to vias without any via pad (“fast via” and designated as “Group A”), while the center vias have the highest number of pads (designated as “Group C”) in this example.

The phase-delay capable vias offer one or more of the following advantages: (1) shorten trace lengths while maintaining a select phase delay for a signal group between host and target devices to reduce insertion loss and/or FEXT; (2) eliminate serpentine routings to free up board real estate for allowing higher density and/or finer pitch ball out on host and target device themselves; (3) allow placement of host and target dies closer to each other to achieve higher component count per square unit of PCB board; and/or (4) tuning of the amount of phase delay on such via(s) and/or optimizing the amount of phase delay for each individual electrical path on a main board and/or silicon package substrates accordingly, e.g., based on platform signal integrity electrical budget needs.

In one or more embodiments, the phase-delay capable vias may be used in Double Data Rate (DDR) memory Dual In-line Memory Module (DIMM) connector to a (e.g., small) chip. The phase-delay capable vias will results in a shorter and/or more dense/cleaner routing between the connector and the chip, and hence it brings the benefits of lower FEXT, lower insertion loss, and/or better impedance control.

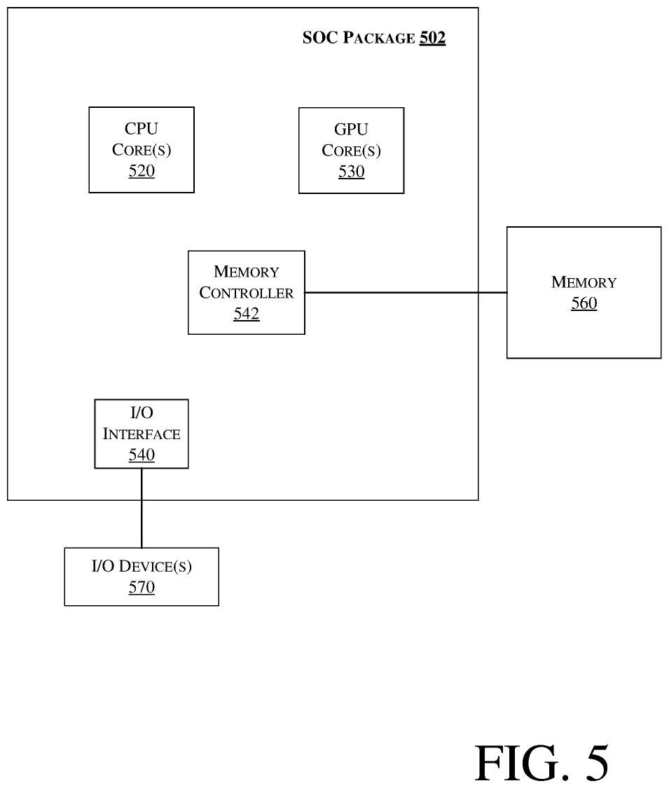

One or more components discussed with reference to FIGS. 5-7 (including but not limited to I/O devices, memory/storage devices, graphics/processing cards/devices, network/bus/audio/display/graphics controllers, wireless transceivers, etc.) may be coupled using the interconnects discussed above. More particularly, FIG. 5 illustrates a block diagram of an SOC package in accordance with an embodiment. As illustrated in FIG. 5, SOC 502 includes one or more Central Processing Unit (CPU) cores 520, one or more Graphics Processor Unit (GPU) cores 530, an Input/Output (I/O) interface 540, and a memory controller 542. Various components of the SOC package 502 may be coupled to an interconnect or bus such as discussed herein with reference to the other figures. Also, the SOC package 502 may include more or less components, such as those discussed herein with reference to the other figures. Further, each component of the SOC package 520 may include one or more other components, e.g., as discussed with reference to the other figures herein. In one embodiment, SOC package 502 (and its components) is provided on one or more Integrated Circuit (IC) die, e.g., which are packaged into a single semiconductor device.

As illustrated in FIG. 5, SOC package 502 is coupled to a memory 560 via the memory controller 542. In an embodiment, the memory 560 (or a portion of it) can be integrated on the SOC package 502.

The I/O interface 540 may be coupled to one or more I/O devices 570, e.g., via an interconnect and/or bus such as discussed herein with reference to other figures. I/O device(s) 570 may include one or more of a keyboard, a mouse, a touchpad, a display, an image/video capture device (such as a camera or camcorder/video recorder), a touch screen, a speaker, or the like.

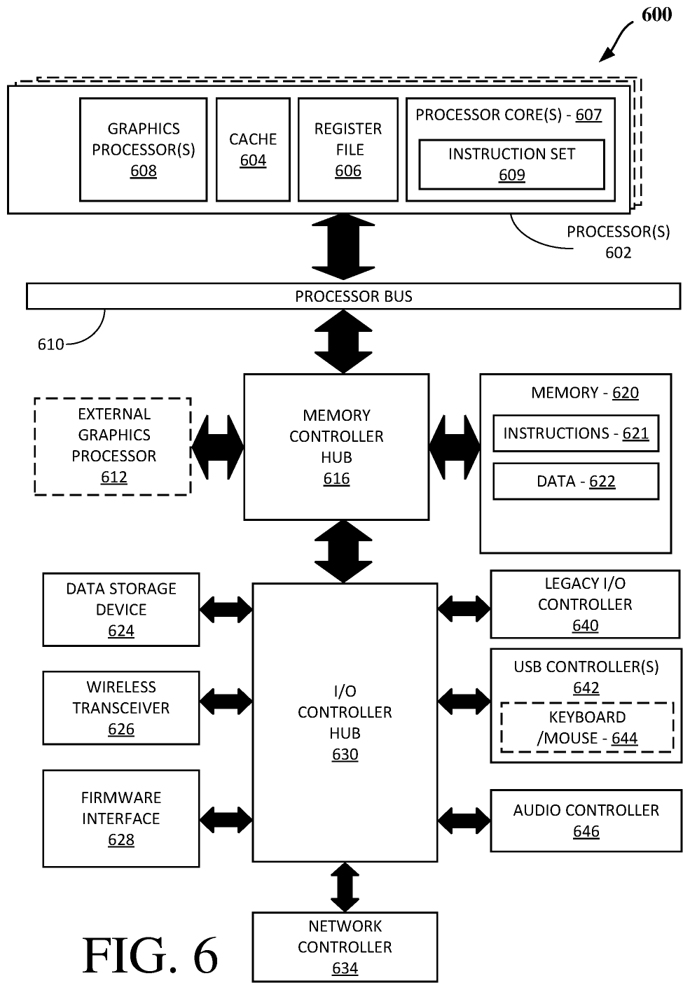

FIG. 6 is a block diagram of a processing system 600, according to an embodiment. In various embodiments the system 600 includes one or more processors 602 and one or more graphics processors 608, and may be a single processor desktop system, a multiprocessor workstation system, or a server system having a large number of processors 602 or processor cores 607. In on embodiment, the system 600 is a processing platform incorporated within a system-on-a-chip (SoC or SOC) integrated circuit for use in mobile, handheld, or embedded devices.

An embodiment of system 600 can include, or be incorporated within a server-based gaming platform, a game console, including a game and media console, a mobile gaming console, a handheld game console, or an online game console. In some embodiments system 600 is a mobile phone, smart phone, tablet computing device or mobile Internet device. Data processing system 600 can also include, couple with, or be integrated within a wearable device, such as a smart watch wearable device, smart eyewear device, augmented reality device, or virtual reality device. In some embodiments, data processing system 600 is a television or set top box device having one or more processors 602 and a graphical interface generated by one or more graphics processors 608.

In some embodiments, the one or more processors 602 each include one or more processor cores 607 to process instructions which, when executed, perform operations for system and user software. In some embodiments, each of the one or more processor cores 607 is configured to process a specific instruction set 609. In some embodiments, instruction set 609 may facilitate Complex Instruction Set Computing (CISC), Reduced Instruction Set Computing (RISC), or computing via a Very Long Instruction Word (VLIW). Multiple processor cores 607 may each process a different instruction set 609, which may include instructions to facilitate the emulation of other instruction sets. Processor core 607 may also include other processing devices, such a Digital Signal Processor (DSP).

In some embodiments, the processor 602 includes cache memory 604. Depending on the architecture, the processor 602 can have a single internal cache or multiple levels of internal cache. In some embodiments, the cache memory is shared among various components of the processor 602. In some embodiments, the processor 602 also uses an external cache (e.g., a Level-3 (L3) cache or Last Level Cache (LLC)) (not shown), which may be shared among processor cores 607 using known cache coherency techniques. A register file 606 is additionally included in processor 602 which may include different types of registers for storing different types of data (e.g., integer registers, floating point registers, status registers, and an instruction pointer register). Some registers may be general-purpose registers, while other registers may be specific to the design of the processor 602.

In some embodiments, processor 602 is coupled to a processor bus 610 to transmit communication signals such as address, data, or control signals between processor 602 and other components in system 600. In one embodiment the system 600 uses an exemplary ‘hub’ system architecture, including a memory controller hub 616 and an Input Output (I/O) controller hub 630. A memory controller hub 616 facilitates communication between a memory device and other components of system 600, while an I/O Controller Hub (ICH) 630 provides connections to I/O devices via a local I/O bus. In one embodiment, the logic of the memory controller hub 616 is integrated within the processor.

Memory device 620 can be a dynamic random access memory (DRAM) device, a static random access memory (SRAM) device, flash memory device, phase-change memory device, or some other memory device having suitable performance to serve as process memory. In one embodiment the memory device 620 can operate as system memory for the system 600, to store data 622 and instructions 621 for use when the one or more processors 602 executes an application or process. Memory controller hub 616 also couples with an optional external graphics processor 612, which may communicate with the one or more graphics processors 608 in processors 602 to perform graphics and media operations.

In some embodiments, ICH 630 enables peripherals to connect to memory device 620 and processor 602 via a high-speed I/O bus. The I/O peripherals include, but are not limited to, an audio controller 646, a firmware interface 628, a wireless transceiver 626 (e.g., Wi-Fi, Bluetooth), a data storage device 624 (e.g., hard disk drive, flash memory, etc.), and a legacy I/O controller 640 for coupling legacy (e.g., Personal System 2 (PS/2)) devices to the system. One or more Universal Serial Bus (USB) controllers 642 connect input devices, such as keyboard and mouse 644 combinations. A network controller 634 may also couple to ICH 630. In some embodiments, a high-performance network controller (not shown) couples to processor bus 610. It will be appreciated that the system 600 shown is exemplary and not limiting, as other types of data processing systems that are differently configured may also be used. For example, the I/O controller hub 630 may be integrated within the one or more processor 602, or the memory controller hub 616 and I/O controller hub 630 may be integrated into a discreet external graphics processor, such as the external graphics processor 612.

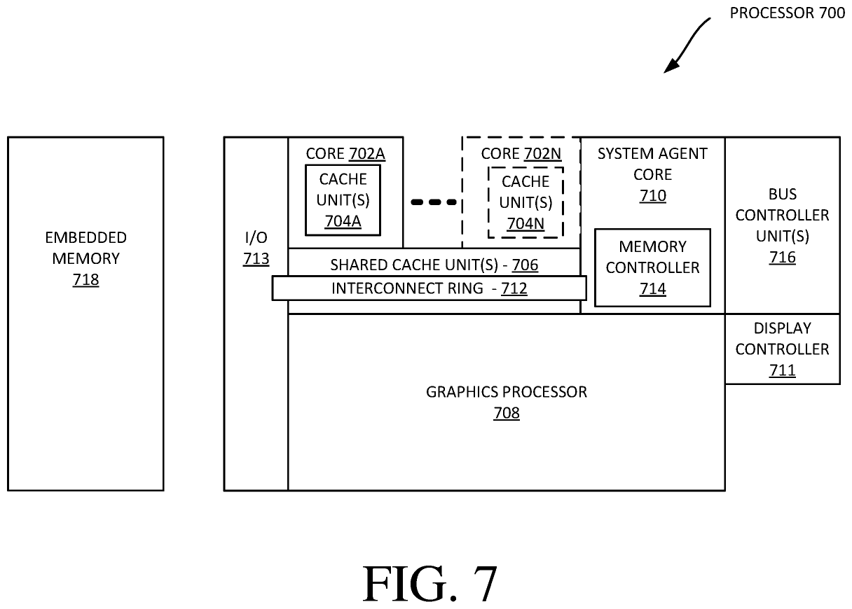

FIG. 7 is a block diagram of an embodiment of a processor 700 having one or more processor cores 702A to 702N, an integrated memory controller 714, and an integrated graphics processor 708. Those elements of FIG. 7 having the same reference numbers (or names) as the elements of any other figure herein can operate or function in any manner similar to that described elsewhere herein, but are not limited to such. Processor 700 can include additional cores up to and including additional core 702N represented by the dashed lined boxes. Each of processor cores 702A to 702N includes one or more internal cache units 704A to 704N. In some embodiments each processor core also has access to one or more shared cached units 706.

The internal cache units 704A to 704N and shared cache units 706 represent a cache memory hierarchy within the processor 700. The cache memory hierarchy may include at least one level of instruction and data cache within each processor core and one or more levels of shared mid-level cache, such as a Level 2 (L2), Level 3 (L3), Level 4 (L4), or other levels of cache, where the highest level of cache before external memory is classified as the LLC. In some embodiments, cache coherency logic maintains coherency between the various cache units 706 and 704A to 704N.

In some embodiments, processor 700 may also include a set of one or more bus controller units 716 and a system agent core 710. The one or more bus controller units 716 manage a set of peripheral buses, such as one or more Peripheral Component Interconnect buses (e.g., PCI, PCI Express). System agent core 710 provides management functionality for the various processor components. In some embodiments, system agent core 710 includes one or more integrated memory controllers 714 to manage access to various external memory devices (not shown).

In some embodiments, one or more of the processor cores 702A to 702N include support for simultaneous multi-threading. In such embodiment, the system agent core 710 includes components for coordinating and operating cores 702A to 702N during multi-threaded processing. System agent core 710 may additionally include a power control unit (PCU), which includes logic and components to regulate the power state of processor cores 702A to 702N and graphics processor 708.

In some embodiments, processor 700 additionally includes graphics processor 708 to execute graphics processing operations. In some embodiments, the graphics processor 708 couples with the set of shared cache units 706, and the system agent core 710, including the one or more integrated memory controllers 714. In some embodiments, a display controller 711 is coupled with the graphics processor 708 to drive graphics processor output to one or more coupled displays. In some embodiments, display controller 711 may be a separate module coupled with the graphics processor via at least one interconnect, or may be integrated within the graphics processor 708 or system agent core 710.

In some embodiments, a ring-based interconnect unit 712 is used to couple the internal components of the processor 700. However, an alternative interconnect unit may be used, such as a point-to-point interconnect, a switched interconnect, or other techniques, including techniques well known in the art. In some embodiments, graphics processor 708 couples with the ring interconnect 712 via an I/O link 713.

The exemplary I/O link 713 represents at least one of multiple varieties of I/O interconnects, including an on package I/O interconnect which facilitates communication between various processor components and a high-performance embedded memory module 718, such as an eDRAM (or embedded DRAM) module. In some embodiments, each of the processor cores 702 to 702N and graphics processor 708 use embedded memory modules 718 as a shared Last Level Cache.

In some embodiments, processor cores 702A to 702N are homogenous cores executing the same instruction set architecture. In another embodiment, processor cores 702A to 702N are heterogeneous in terms of instruction set architecture (ISA), where one or more of processor cores 702A to 702N execute a first instruction set, while at least one of the other cores executes a subset of the first instruction set or a different instruction set. In one embodiment processor cores 702A to 702N are heterogeneous in terms of microarchitecture, where one or more cores having a relatively higher power consumption couple with one or more power cores having a lower power consumption. Additionally, processor 700 can be implemented on one or more chips or as an SoC integrated circuit having the illustrated components, in addition to other components.

The following examples pertain to further embodiments. Example 1 includes an interconnect comprising: a plurality of links, wherein a first set of links from the plurality of links is to communicate signals and a second set of links from the plurality of links is to provide a return path; and one or more links from the first set of links to comprise one or more structures with a larger diameter than a minimum diameter of the one or more links, wherein the larger diameter is to modify an inductance or capacitance of the one or more links to provide a heterogenous phase delay amongst the plurality of links. Example 2 includes the interconnect of example 1, wherein the one or more structures are to be dispersed non-uniformly along at least one of the one or more links. Example 3 includes the interconnect of example 1, wherein the one or more structures are to be dispersed uniformly along at least one of the one or more links. Example 4 includes the interconnect of example 1, wherein the one or more structures are to have a circular shape, a square shape, a rectangular shape, a sawtooth shape, or combinations thereof. Example 5 includes the interconnect of example 1, wherein the one or more structures are to have differing thicknesses.

Example 6 includes the interconnect of example 1, wherein the one or more structures are to be dispersed: within one or more layers of a multi-layer Printed Circuit Board (PCB), at one or more transition points between two adjoining layers of the multi-layer PCB, or combinations thereof. Example 7 includes the interconnect of example 1, wherein at least one of the first set of links or the second set of links comprises a through-hole via or a partial through-hole via. Example 8 includes the interconnect of example 7, wherein partial through-hole via comprises a blind via or buried via. Example 9 includes the interconnect of example 7, wherein the through-hole via is plated with a conductive material. Example 10 includes the interconnect of example 9, wherein the conductive material is one of copper, nickel, and aluminum.

Example 11 includes the interconnect of example 1, further comprising a PCB to mechanically couple the plurality of links, wherein the PCB is to be surface finished with Hot Air Solder Leveling (HASL) finish, lead free HASL finish, or Electroless Nickel Immersion Gold (ENIG) finish. Example 12 includes the interconnect of example 1, wherein the larger diameter is approximately 20% to 30% larger than the minimum diameter of the one or more links. Example 13 includes the interconnect of example 1, wherein the return path comprises a path to ground. Example 14 includes a system comprising: a Printed Circuit Board (PCB) having a plurality of vias; a plurality of links, wherein a first set of links from the plurality of links is to communicate signals and a second set of links from the plurality of links is to provide a return path; and one or more links from the first set of links to comprise one or more structures with a larger diameter than a minimum diameter of the one or more links, wherein the larger diameter is to modify an inductance or capacitance of the one or more links to provide a heterogenous phase delay amongst the plurality of links.

Example 15 includes the system of example 14, wherein the one or more structures are to be dispersed non-uniformly along at least one of the one or more links. Example 16 includes the system of example 14, wherein the one or more structures are to be dispersed uniformly along at least one of the one or more links.

Example 17 includes the system of example 14, wherein the one or more structures are to have a circular shape, a square shape, a rectangular shape, a sawtooth shape, or combinations thereof. Example 18 includes the system of example 14, wherein the one or more structures are to have differing thicknesses. Example 19 includes the system of example 14, wherein the PCB comprises a multi-layer PCB, wherein the one or more structures are to be dispersed: within one or more layers of the multi-layer PCB, at one or more transition points between two adjoining layers of the multi-layer PCB, or combinations thereof. Example 20 includes the system of example 14, wherein at least one of the first set of links or the second set of links comprises one or more of the plurality of vias, wherein each of the plurality of vias comprises a through-hole via or a partial through-hole via. Example 21 includes an apparatus comprising means to perform a method as set forth in any preceding example.

In various embodiments, the operations discussed herein, e.g., with reference to FIGS. 1 et seq., may be implemented as hardware (e.g., logic circuitry or more generally circuitry or circuit), software, firmware, or combinations thereof, which may be provided as a computer program product, e.g., including a tangible (e.g., non-transitory) machine-readable or computer-readable medium having stored thereon instructions (or software procedures) used to program a computer to perform a process discussed herein. The machine-readable medium may include a storage device such as those discussed with respect to FIGS. 1 et seq.

Additionally, such computer-readable media may be downloaded as a computer program product, wherein the program may be transferred from a remote computer (e.g., a server) to a requesting computer (e.g., a client) by way of data signals provided in a carrier wave or other propagation medium via a communication link (e.g., a bus, a modem, or a network connection).

Reference in the specification to “one embodiment” or “an embodiment” means that a particular feature, structure, and/or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

Thus, although embodiments have been described in language specific to structural features and/or methodological acts, it is to be understood that claimed subject matter may not be limited to the specific features or acts described. Rather, the specific features and acts are disclosed as sample forms of implementing the claimed subject matter.

1. An interconnect comprising:
a plurality of links, wherein a first set of links from the plurality of links is to communicate signals and a second set of links from the plurality of links is to provide a return path; and
one or more links from the first set of links to comprise one or more structures with a larger diameter than a minimum diameter of the one or more links,
wherein the larger diameter is to modify an inductance or capacitance of the one or more links to provide a heterogenous phase delay amongst the plurality of links.

2. The interconnect of claim 1, wherein the one or more structures are to be dispersed non-uniformly along at least one of the one or more links.

3. The interconnect of claim 1, wherein the one or more structures are to be dispersed uniformly along at least one of the one or more links.

4. The interconnect of claim 1, wherein the one or more structures are to have a circular shape, a square shape, a rectangular shape, a sawtooth shape, or combinations thereof.

5. The interconnect of claim 1, wherein the one or more structures are to have differing thicknesses.

6. The interconnect of claim 1, wherein the one or more structures are to be dispersed: within one or more layers of a multi-layer Printed Circuit Board (PCB), at one or more transition points between two adjoining layers of the multi-layer PCB, or combinations thereof.

7. The interconnect of claim 1, wherein at least one of the first set of links or the second set of links comprises a through-hole via or a partial through-hole via.

8. The interconnect of claim 7, wherein partial through-hole via comprises a blind via or buried via.

9. The interconnect of claim 7, wherein the through-hole via is plated with a conductive material.

10. The interconnect of claim 9, wherein the conductive material is one of copper, nickel, and aluminum.

11. The interconnect of claim 1, further comprising a PCB to mechanically couple the plurality of links, wherein the PCB is to be surface finished with Hot Air Solder Leveling (HASL) finish, lead free HASL finish, or Electroless Nickel Immersion Gold (ENIG) finish.

12. The interconnect of claim 1, wherein the larger diameter is approximately 20% to 30% larger than the minimum diameter of the one or more links.

13. The interconnect of claim 1, wherein the return path comprises a path to ground.

14. A system comprising:
a Printed Circuit Board (PCB) having a plurality of vias;
a plurality of links, wherein a first set of links from the plurality of links is to communicate signals and a second set of links from the plurality of links is to provide a return path; and
one or more links from the first set of links to comprise one or more structures with a larger diameter than a minimum diameter of the one or more links,
wherein the larger diameter is to modify an inductance or capacitance of the one or more links to provide a heterogenous phase delay amongst the plurality of links.

15. The system of claim 14, wherein the one or more structures are to be dispersed non-uniformly along at least one of the one or more links.

16. The system of claim 14, wherein the one or more structures are to be dispersed uniformly along at least one of the one or more links.

17. The system of claim 14, wherein the one or more structures are to have a circular shape, a square shape, a rectangular shape, a sawtooth shape, or combinations thereof.

18. The system of claim 14, wherein the one or more structures are to have differing thicknesses.

19. The system of claim 14, wherein the PCB comprises a multi-layer PCB, wherein the one or more structures are to be dispersed: within one or more layers of the multi-layer PCB, at one or more transition points between two adjoining layers of the multi-layer PCB, or combinations thereof.

20. The system of claim 14, wherein at least one of the first set of links or the second set of links comprises one or more of the plurality of vias, wherein each of the plurality of vias comprises a through-hole via or a partial through-hole via.
